(19) United States
(12) Patent Application Publication
(10) Pub. No.: US 2024/0027539 A1
(43) Pub. Date: Jan. 25, 2024

(54) Surface-Penetrating Radar For Monitoring Vehicle Battery Health

(71) Applicant: GPR, Inc., Somerville, MA (US)

(72) Inventors: Daniel Jamison, Somerville, MA (US); Louis Arthur Paquette, Temple, NH (US); Byron Stanley, Newton, MA (US)

(21) Appl. No.: 18/354,982

(22) Filed: Jul. 19, 2023

Related U.S. Application Data
(60) Provisional application No. 63/390,471, filed on Jul. 19, 2022.

(51) Int. Cl. G01R 31/392; G01S 13/89

(52) U.S. Cl. CPC G01R 31/392; G01S 13/89

(57) ABSTRACT

A system for monitoring vehicle battery health having a radar antenna array, a SPR system and a battery system. The radar antenna array transmitting and receiving SPR signals. The SPR system driving the antennas to emit radar signals and receive reflection signals, and analyzing the received reflection signals. At least a portion of the battery system being disposed within a cavity of the SPR system. The SPR system detecting a condition of the battery system based on analysis of the received reflection signals.

### CROSS-REFERENCE TO RELATED APPLICATIONS

This application claims the benefit of U.S. Provisional Patent Application No. 63/390,471 filed Jul. 19, 2022 entitled “Surface-Penetrating Radar for Monitoring Vehicle Battery Health”, which is incorporated by reference herein in its entirety.

### TECHNICAL FIELD

The present disclosure generally relates to vehicle batteries and, more particularly, to monitoring the health of vehicle batteries using surface-penetrating radar (SPR).

### SUMMARY

In certain embodiments, a vehicle battery health monitoring system may comprise a radar antenna array, a SPR system and a battery system. The radar antenna array may include at least one antenna configured to transmit and receive surface-penetrating radar (SPR) signals. The SPR system may be for (i) controlling the antenna to emit radar signals and receive reflection signals and (ii) analyzing the received reflection signals. At least a portion of the battery system may be disposed within a cavity of the SPR system. In certain embodiments, the SPR system may be configured to detect a condition of the battery system based on analysis of the received reflection signals.

In certain embodiments, the system may further comprise a computer memory for storing a pedigree SPR image associated with the battery system, the SPR system may be configured to detect the condition based on comparison of a current SPR image with the pedigree SPR image. In certain embodiments, the SPR system may be configured to detect an approximate location of the condition. The condition may be: physical; chemical; a change in dielectric properties; a change in electrolyte properties; and/or a change in electrolyte distribution.

In certain embodiments, a method of monitoring a condition associated with a vehicle battery system may include the steps of: transmitting SPR signals via a radar antenna array; analyzing, with a SPR system, reflections of the transmitted SPR signals associated with the battery system, at least a portion of the battery system being disposed within a cavity of the SPR system; and detecting a condition of the battery system based on the analysis.

In certain embodiments, the condition may be detected based on comparison of a current SPR image with a previously obtained SPR image. In certain embodiments, the condition may be detected based on a change in dielectric properties. In certain embodiments, the condition may be: mechanical, physical, or chemical; a change in dielectric properties; a change in electrolyte properties; and/or a change in electrolyte distribution.

### BRIEF DESCRIPTION OF THE DRAWINGS

The foregoing summary, as well as the following detailed description of embodiments of the system, will be better understood when read in conjunction with the appended drawings of an exemplary embodiment. It should be understood, however, that the invention is not limited to the precise arrangements and instrumentalities shown.

In the drawings:

FIG. 1 schematically depicts an exemplary surface penetrating radar (SPR) system in accordance with embodiments of the invention;

FIG. 2A is a side view of a vehicle including the SPR system of FIG. 1;

FIG. 2B is a front view of a vehicle including the SPR system of FIG. 1; and

FIG. 3 is a partial side view of a vehicle including the SPR system of FIG. 1.

### DETAILED DESCRIPTION

Vehicle batteries are unavoidably prone to some swelling due to, for example, their construction and environmental factors. In winter, a battery may swell because of frozen electrolytes, while summer heat may cause swelling due to the release of gas within the battery casing. Seasonal swelling is common and generally does not compromise the health of the battery. However, other factors can cause more significant degrees of swelling that do affect battery function and can ultimately cause failure. These may include manufacturing faults, condensed or frozen electrolytes that have lost density, damage to the battery's case due to an impact or mechanical stress, short circuits, improper battery charging (e.g., excessive applied current or current applied for too long), or a malfunctioning voltage regulator in the alternator. Further, mechanical or other damage to the battery, or other adverse conditions affecting operation, may not appear as swelling but nonetheless impair or degrade battery performance. For example, chemical anomalies affecting the electrolyte may not have any visible manifestation.

It can be difficult, from simple visual inspection, to detect swelling or damage to a battery until the swelling is so advanced that failure is imminent and the battery must be replaced; and in any case, such visual inspections are rarely performed. Accordingly, there is a need for convenient measures to monitor adverse battery conditions that can affect performance and prompt remedial action to preserve battery health while ignoring expected, harmless changes in battery volume that occur seasonally. While battery health is important in any vehicle, the increasing prevalence of electric vehicles, with their much larger and far more expensive batteries, makes the ability to detect early signs of impending failure increasingly important.

As described in U.S. Pat. No. 10,935,655, the entire disclosure of which is hereby

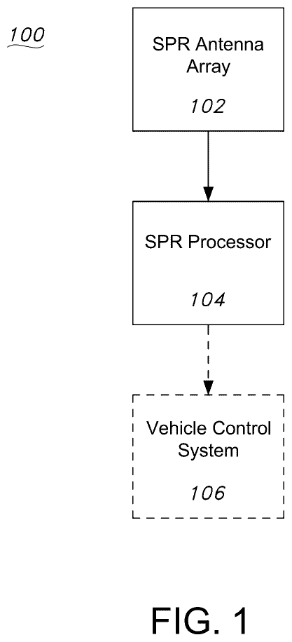

incorporated by reference, a vehicle battery may be integrated at least partially within the cavity of a surface-penetrating radar (SPR) system used for other purposes, e.g., vehicle navigation. With reference to FIG. 1, a representative mobile SPR system 100 includes a SPR antenna array 102, which, as detailed below, may be mounted to the underside of a vehicle. The SPR antenna array 102 may include one or more antenna elements for transmitting and receiving radar signals. A conventional

SPR processor 104 may control the transmit operations of SPR antenna array 102 and receive return radar signals for analysis. The detected SPR signals may be processed to generate one or more SPR images of the subsurface region along the track of the vehicle to which the SPR antenna array 102 is mounted. If the SPR antenna array 102 is not in contact with the surface, the strongest return signal received may be the reflection caused by the road surface. Thus, the SPR images may include surface data, i.e., data for the interface of the subsurface region with air or the local environment. Suitable SPR antenna configurations and systems for processing SPR signals are described, for example, in U.S. Pat. No. 8,949,024, the entire disclosure of which is hereby incorporated by reference.

For navigation applications, the SPR images may be compared to SPR reference images that were previously acquired and stored for subsurface regions that at least partially overlap the subsurface regions for the defined route. The image comparison may be a registration process based on, for example, correlation; see, e.g., U.S. Pat. No. 8,786,485, the entire disclosure of which is incorporated by reference herein. The location of the vehicle and/or the terrain conditions of the route may then be determined based on the comparison.

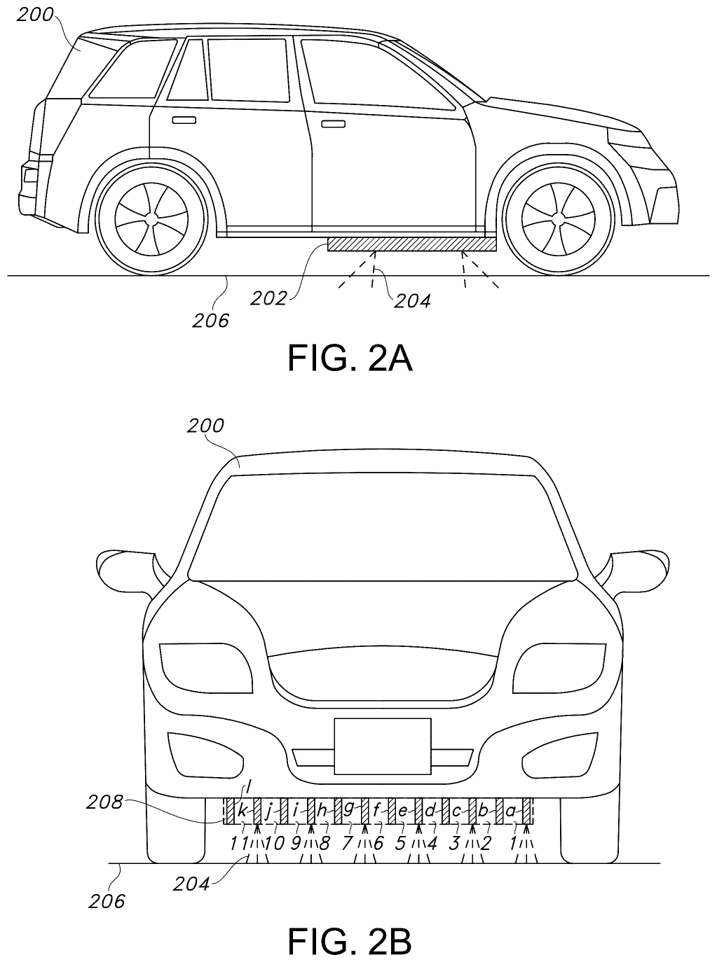

With reference to FIGS. 2A and 2B, a vehicle 200, which may be any mobile platform or structure, includes an SPR system 202 that transmits SPR signals 204 from a plurality of SPR transmit elements of a SPR antenna array 208. The SPR antenna array 208 may include, illustratively, a linear configuration of 12 spatially invariant transmit and receive antenna elements (a) through (1) for transmitting and receiving radar signals. The twelve antenna elements may form eleven channels (1) through (11). Each channel may include a transmit element and a receive element or a transmit pair and a receive pair.

The SPR antenna array 208 may be nominally or substantially parallel to the ground surface 206 and may extend parallel or perpendicular to the direction of travel of the vehicle 200. SPR signals 204 may propagate downward from the transmitting antenna elements to and/or through the road surface 206 under the vehicle 200. The SPR signals 204 may be backscattered upwardly from the surface 206 or subsurface of the road and may be detected by the receiving antenna elements. The upper part of the antenna array 208 can be integrated below or in between sections of the battery and may involve any of various antenna form factors such as a horn antenna or a bowtie, as are typically used for GPR applications. The horn type may be integrated vertically, the bowtie underneath or on top (if used to detect ground reflections). The bowtie form factor may enable mounting of the antenna array 208 below the battery cells. The horn antenna form factor may provide gains in directionality of the antenna array 208. Improved directionality may allow for improved or further optimized design though rf transparent areas of the horn antenna form. The rf transparent areas area may be designed to enable SPR signals 204 to interact with and/or reflect off the battery cells. Alternatively, the antenna cavity itself may reradiate at certain frequencies in both the horn and bowtie configurations towards the cells, which enables detecting the differences in the battery cells discussed below.

While the SPR signals 204 are shown in FIG. 2B as being directed downwardly toward the surface 206, the signals and waves emitted by the SPR antenna array may propagate in all directions including upwards toward the vehicle 200. These signals may ultimately reflect from various components and materials (e.g., battery components in the case of an electric vehicle) and may ultimately be scattered downwardly or in other directions.

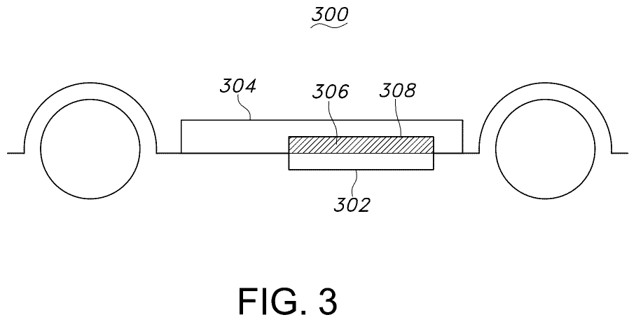

The SPR system 202 may have a cavity above the SPR antenna array 208. The cavity may provide a uniform environment for waves emitted from the SPR antenna array 208 to be reflected, slowed, or absorbed so as to improve overall signal quality. With reference to FIG. 3, a vehicle 300 may include a SPR system 302 (and an antenna array as discussed above but not shown in FIG. 3). The vehicle 300 may also include a battery system 304. Battery systems for electric vehicles may be much larger than battery systems for fuel powered vehicles. A battery system 304 for an electric vehicle may be mounted underneath the vehicle 300. Such battery systems may include many individual units or cells (e.g., over 4000 cells) and each cell may be relatively small (e.g., 18 mm) in diameter. The cells may include electrolytes including salts, such as lithium-ion salts. The battery system 304 may span all or part of the base of the vehicle 300 and may, thus, take up a large part of the vehicle's 300 underside. The battery system 304 may, for example, be built into or on top of a chassis or base of the vehicle 300.

At least a portion (e.g., portion 306) of the battery system 304 of the vehicle 300 may also be at least a portion of the SPR system 302, e.g., a portion of the cavity of the SPR system 302. This being the case, signals received by the SPR system 302 may be used to diagnose battery conditions.

In particular, signal components relating to (e.g., reflected from) the battery system 304 may be readily distinguished from those representing surface and subsurface road features based on time of flight, since the battery cavity is much closer to the antenna array 208 than to the ground or other reflective surface. When the battery is fresh, a pedigree SPR signature (e.g., image) can be obtained and stored. Over time, new SPR signal reflections from the battery system 304 may be periodically obtained and compared against the pedigree signature.

It may be useful to isolate the signatures of return signals when the battery return arrives later than the initial ground bounce or return from other clutter sources. In this case, the signatures of return signals from the battery may be isolated and analyzed. As described above, signals from an intact battery may be stored as a pedigree signature. It may be possible to obtain signatures from batteries exhibiting different types of damage or other conditions affecting performance and use these signatures as diagnostic templates. A new signature within the main return may be compared to these templates using a suitable signal-processing method such as pattern detection, mean removal, singular value decomposition, etc. with a processor (e.g., SPR processor 104).

The SPR processor 104 may create a transfer function of the environment by analyzing the magnitude and phase of the SPR signals 204 returned from the target (e.g., the battery) over time. The collection and analysis of data may occur while stationary or while moving. By collecting and analyzing data in a location with known reflection signatures (e.g., a known location such as the chassis of vehicle 200), changes in the reflection signature received from the battery may be isolated from the reflection signature received from the known location. Further, the reflection signature (i.e., the time and phase) of the SPR signals 204 returned from the ground surface may be used to isolate the immediate reflection signature received from the battery and its surrounding structure.

Monitored conditions can be physical or chemical (or both) in nature. One physical condition that can be monitored, for example, is swelling. A larger battery may have more reflective surface and a detectably different return signature from a battery without swelling. Another condition is redistribution of electrolyte within the battery system 304 due to battery damage. The reflective properties specific to the electrolyte may manifest themselves in a SPR image based on their distribution within the battery. If reflective properties specific to the electrolyte change, the SPR image or image regions attributable to reflections from the battery may also change. Other physical conditions that can be detected include physical damage to or degradation of the battery or battery connectors/wiring, e.g., if a battery is physically altered during an impact, if a connector or wire comes loose, if corrosion begins to form on the contacts, miswiring and improper installation, or if the battery is missing entirely.

Chemical conditions or anomalies that may be monitored include degradation of the electrolyte (due, for example, to excessive heat), which may detectably change its dielectric, permeability or lossiness properties even if its distribution is unchanged. When anomalies are detected in the SPR image, the SPR processor 104 may, upon detection of the condition, directly or indirectly alert the vehicle owner or otherwise signal the existence of the condition. In many cases, the location of the failure can be detected in relation to the SPR array (e.g., the anomaly can be localized to the region above a particular antenna, enabling technicians to begin inspection where the problem is likely to be visible). In addition, the system may detect and issue an alert when the current environment may be harmful to batteries, or gauge how harmful the current environment is, in order to prevent battery corrosion or damage over time. In particular, the SPR processor 104 may monitor humidity or temperature extremes, or vibration levels that may cause battery damage, inside the battery cavity itself and issue an alert when the condition is detected or if it persists for an unacceptably long period of time. More generally, machine-learning techniques can be used to determine and detect different battery failure modes within an SPR environment. For example, machine-learning may be used to map a range of difference convolutions found in the SPR image to highlight target features and frequency changes associated with battery damage.

The SPR processor 104 may include one or more modules implemented in hardware, software, or a combination of both. For embodiments in which the functions are provided as one or more software programs, the programs may be written in any of a number of high-level languages such as PYTHON, FORTRAN, PASCAL, JAVA, C, C++, C#, BASIC, various scripting languages, and/or HTML. Additionally, the software can be implemented in an assembly language directed to the microprocessor resident on a target computer; for example, the software may be implemented in Intel 80×86 assembly language if it is configured to run on an IBM PC or PC clone. The software may be embodied on an article of manufacture including, but not limited to, a floppy disk, a jump drive, a hard disk, an optical disk, a magnetic tape, a PROM, an EPROM, EEPROM, field-programmable gate array, or CD-ROM. Embodiments using hardware circuitry may be implemented using, for example, one or more FPGA, CPLD or ASIC processors.

The term “about” or “approximately” is used herein to provide literal support for the exact number that it precedes, as well as a number that is near to or approximately the number that the term precedes. In determining whether a number is near to or approximately a specifically recited number, the near or approximating unrecited number may be a number, which, in the context in which it is presented, provides the substantial equivalent of the specifically recited number. It should be appreciated that all numerical values and ranges disclosed herein are approximate values and ranges, whether “about” is used in conjunction therewith. It should also be appreciated that the term “about,” as used herein, in conjunction with a numeral refers to a value that may be ±0.01% (inclusive), ±0.1% (inclusive), ±0.5% (inclusive), ±1% (inclusive) of that numeral, ±2% (inclusive) of that numeral, ±3% (inclusive) of that numeral, ±5% (inclusive) of that numeral, ±10% (inclusive) of that numeral, or ±15% (inclusive) of that numeral. It should further be appreciated that when a numerical range is disclosed herein, any numerical value falling within the range is also specifically disclosed.

It will be appreciated by those skilled in the art that changes could be made to the exemplary embodiments shown and described above without departing from the broad inventive concepts thereof. It is to be understood that the embodiments and claims disclosed herein are not limited in their application to the details of construction and arrangement of the components set forth in the description and illustrated in the drawings. Rather, the description and the drawings provide examples of the embodiments envisioned. The embodiments and claims disclosed herein are further capable of other embodiments and of being practiced and carried out in various ways.

Specific features of the exemplary embodiments may or may not be part of the claimed

invention and various features of the disclosed embodiments may be combined. Unless specifically set forth herein, the terms “a”, “an” and “the” are not limited to one element but instead should be read as meaning “at least one”. Finally, unless specifically set forth herein, a disclosed or claimed method should not be limited to the performance of their steps in the order written, and one skilled in the art can readily appreciate that the steps may be performed in any practical order.

What is claimed is:

1. A vehicle battery health monitoring system comprising:
a radar antenna array including at least one antenna configured to transmit and receive surface-penetrating radar (SPR) signals;
a SPR system for (i) controlling the antenna to emit radar signals and receive reflection signals and (ii) analyzing the received reflection signals; and
a battery system, at least a portion of the battery system being disposed within a cavity of the SPR system,
wherein the SPR system is configured to detect a condition of the battery system based on analysis of the received reflection signals.

2. The system of claim 1, further comprising a computer memory for storing a pedigree SPR image associated with the battery system, the SPR system being configured to detect the condition based on comparison of a current SPR image with the pedigree SPR image.

3. The system of claim 1, wherein the SPR system is configured to detect an approximate location of the condition.

4. The system of claim 1, wherein the condition is physical.

5. The system of claim 1, wherein the condition is chemical.

6. The system of claim 1, wherein the condition is a change in dielectric properties.

7. The system of claim 6, wherein the condition is a change in electrolyte properties.

8. The system of claim 5, wherein the condition is a change in electrolyte distribution.

9. A method of monitoring a condition associated with a vehicle battery system, the method comprising the steps of:
transmitting SPR signals via a radar antenna array;
analyzing, with a SPR system, reflections of the transmitted SPR signals associated with the battery system, at least a portion of the battery system being disposed within a cavity of the SPR system; and
detecting a condition of the battery system based on the analysis.

10. The method of claim 9, wherein the condition is detected based on comparison of a current SPR image with a previously obtained SPR image.

11. The method of claim 9, wherein the condition is detected based on a change in dielectric properties.

12. The method of claim 9, wherein the condition is mechanical, physical, or chemical.

13. The method of claim 12, wherein the condition is a change in dielectric properties.

14. The method of claim 12, wherein the condition is a change in electrolyte properties.

15. The method of claim 12, wherein the condition is a change in electrolyte distribution.
